(19) United States
(12) Patent Application Publication
(10) Pub. No.: US 2007/0256815 A1
(43) Pub. Date: Nov. 8, 2007

(54) Scalable liquid cooling system with modular radiators

(75) Inventors: Bruce Conway, La Honda, CA (US); Richard Brewer, Foster City, CA (US); James Hom, Redwood City, CA (US)

Correspondence Address: HAVERSTOCK & OWENS LLP, 162 N WOLFE ROAD, SUNNYVALE, CA, 94086, US

(73) Assignee: Cooligy, Inc.

(21) Appl. No.: 11/800,275

(22) Filed: May 3, 2007

Related U.S. Application Data
(60) Provisional application No. 60/797,955, filed on May 4, 2006.

(51) Int. Cl. H05K 7/20

(52) U.S. Cl. 165/80.4; 165/104.14; 361/697; 361/699

(57) ABSTRACT

A scalable and modular cooling system is disclosed. The cooling system includes an air plenum with a plurality of expansion slots. Each expansion slot is configured to receive a modularly configured fluid-to-air heat exchanger, such as a radiator. The air plenum also include one or more air movers for blowing air through the expansion slots, and therefore through any radiators fitted within the expansion slots. For those expansion slots that are not used, a blanking plate is fitted to each unused expansion slot. Each blanking plate is modularly configured in a manner similar to the modularly configured radiators. In this manner, air bypass is substantially prevented. Each radiator is part of an independent cooling loop, used directly or indirectly to cool heat generating devices.

### RELATED APPLICATIONS

This Patent Application claims priority under 35 U.S.C. 119(e) of the co-pending U.S. Provisional Patent Application Ser. No. 60/797,955 filed May 4, 2006, and entitled “LIQUID COOLING THROUGH REMOTE DRIVE BAY HEAT EXCHANGER”. The Provisional Patent Application Ser. 60/797,955 filed May 4, 2006, and entitled “LIQUID COOLING THROUGH REMOTE DRIVE BAY HEAT EXCHANGER” is also hereby incorporated by reference.

### FIELD OF THE INVENTION

The invention relates to a method of and apparatus for cooling a heat producing device in general, and specifically, to a method of and apparatus for cooling heat generating devices within a personal computer using a scalable liquid-based cooling system with modular radiators.

### BACKGROUND OF THE INVENTION

Cooling of high performance integrated circuits with high heat dissipation is presenting significant challenge in the electronics cooling arena. Conventional cooling with heat pipes and fan mounted heat sinks are not adequate for cooling chips with every increasing wattage requirements.

A particular problem with cooling integrated circuits within personal computers is that more numerous and powerful integrated circuits are configured within the same size or small personal computer chassis. As more powerful integrated circuits are developed, each with an increasing density of heat generating transistors, the heat generated by each individual integrated circuit continues to increase. Further, more and more integrated circuits, such as graphics processing units, microprocessors, and multiple-chip sets, are being added to personal computers. Still further, the more powerful and more plentiful integrated circuits are being added to the same, or small size personal computer chassis, thereby increasing the per unit heat generated for these devices. In such configurations, conventional personal computer chassis' provide limited dimensions within which to provide an adequate cooling solution. Conventionally, the integrated circuits within a personal computer are cooled using a heat sink and a large fan that blows air over the heat sink, or simply by blowing air directly over the circuit boards containing the integrated circuits. However, considering the limited free space within the personal computer chassis, the amount of air available for cooling the integrated circuits and the space available for conventional cooling equipment, such as heat sinks and fans, is limited.

Closed loop liquid cooling presents alternative methodologies for conventional cooling solutions. Closed loop liquid cooling solutions more efficiently reject heat to the ambient than air cooling solutions.

Conventional personal computers are being developed with ever increasing configurability, including the ability to upgrade existing components and to add new ones. With each upgrade and/or addition, increasing cooling demands are placed on the existing cooling system. Most existing cooling systems are left as is with the expectation that their current cooling capacity is sufficient to accommodate the added cooling load placed by the new or upgraded components. Alternatively, existing cooling systems are completely replaced with a new cooling system with a greater cooling capacity. Existing cooling systems can also be upgraded, but this requires splicing into the existing cooling system to add additional cooling components. In the case of liquid cooling systems, an upgrade requires opening a sealed cooling system to add capacity. Such a process is labor intensive and requires the existing liquid based cooling system to be removed from the personal computer to avoid possible damage to the internal electronic components due to fluid leaks.

What is needed is a more efficient cooling methodology for cooling integrated circuits within a personal computer. What is also needed is a more efficient cooling methodology for cooling integrated circuits on multiple circuit boards mounted within a personal computer chassis. What is still further needed is a cooling methodology that is scalable to meet the scalable configurations of today's personal computers.

### SUMMARY OF THE INVENTION

A scalable and modular cooling system is disclosed. The cooling system includes an air plenum with a plurality of expansion slots. Each expansion slot is configured to receive a modularly configured fluid-to-air heat exchanger, such as a radiator. The air plenum also includes one or more air movers for blowing air through the expansion slots, and therefore through any radiators fitted within the expansion slots. For those expansion slots that are not used, a blanking plate is fitted to each unused expansion slot. Each blanking plate is modularly configured in a manner similar to the modularly configured radiators. In this manner, air bypass is substantially prevented. Each radiator is part of an independent cooling loop, used directly or indirectly to cool heat generating devices.

In one aspect, a cooling system for cooling one or more heat generating devices within a personal computer is disclosed. The cooling system includes one or more independent fluid-based cooling loops, each cooling loop including a modular fluid-to-air heat exchanger and a fluid flowing therethrough, one or more air movers configured to provide air to the fluid-to-air heat exchanger of each cooling loop, and an air plenum including a first end and a second end, wherein the first end is coupled to the one or more air movers and the second end is coupled to multiple receiving bays, wherein each receiving bay is configured to accommodate one removable fluid-to-air heat exchanger from a corresponding cooling loop, further wherein each receiving bay is configured to accommodate one removable blanking plate such that each receiving bay is configured with one fluid-to-air heat exchanger or one blanking plate. Each modular fluid-to-air heat exchanger can be configured to be stacked with another modular fluid-to-air heat exchanger present within an adjacent receiving bay. Each modular fluid-to-air heat exchanger can also be configured to be interlocked with another modular fluid-to-air heat exchanger present within an adjacent receiving bay. Each modular fluid-to-air heat exchanger, each blanking plate, and the second end of the air plenum are configured to substantially prevent air bypass through the second end of the air plenum. The one or more air movers and the first end of the air plenum are configured to substantially prevent air bypass through the first end of the air plenum. Each blanking plate can be configured to prevent air from flowing through the receiving bay to which the blanking plate is coupled. Alternatively, each blanking plate can include one or more air thru-holes, wherein a number of air thru-holes and a dimension of each air thru-hole is configured to provide a specific air flow-through rate through the receiving bay to which the blanking plate is coupled. In some embodiments, the air flow-through rate of each blanking plate can substantially equals an air-flow-through rate through the receiving bay to which one modular fluid-to-air heat exchanger is coupled, thereby generating a substantially equal air flow-through rate through each receiving bay. Each cooling loop can also include one or more heat exchangers and a pump. In some embodiments, each air mover comprises a fan and each fluid-to-air heat exchanger comprises a radiator.

In another aspect, another cooling system for cooling one or more heat generating devices within a personal computer is disclosed. The cooling system includes one or more independent fluid-based cooling loops, each cooling loop including a modular fluid-to-air heat exchanger and a fluid flowing therethrough, one or more air movers configured to provide air to the fluid-to-air heat exchanger of each cooling loop, and an air plenum including a first end and a second end, wherein the first end is coupled to the one or more air movers and the second end is coupled to multiple expansion slots, wherein each expansion slot is configured to receive one removable fluid-to-air heat exchanger from a corresponding cooling loop such that each expansion slot that receives one fluid-to-air heat exchanger is a used expansion slot and each expansion slot that does not receive one fluid-to-air heat exchanger is an unused expansion slot, further wherein each unused expansion slot is configured to receive one removable blanking plate. Each modular fluid-to-air heat exchanger can be configured to be stacked with another modular fluid-to-air heat exchanger present within an adjacent expansion slot. Each modular fluid-to-air heat exchanger can also be configured to be interlocked with another modular fluid-to-air heat exchanger present within an adjacent expansion slot. Each modular fluid-to-air heat exchanger, each blanking plate, and the second end of the air plenum are configured to substantially prevent air bypass through the second end of the air plenum. The one or more air movers and the first end of the air plenum are configured to substantially prevent air bypass through the first end of the air plenum. Each blanking plate can be configured to prevent air from flowing through the expansion slot to which the blanking plate is coupled. Alternatively, each blanking plate can include one or more air thru-holes, wherein a number of air thru-holes and a dimension of each air thru-hole is configured to provide a specific air flow-through rate through the expansion slot to which the blanking plate is coupled. In some embodiments, the air flow-through rate of each blanking plate substantially equals an air-flow-through rate through the expansion slot to which one modular fluid-to-air heat exchanger is coupled, thereby generating a substantially equal air flow-through rate through each expansion slot. Each cooling loop can also include one or more heat exchangers and a pump. In some embodiments, each air mover comprises a fan and each fluid-to-air heat exchanger comprises a radiator.

In yet another aspect, each of the cooling system described above can be configured to accommodate radiator(s) and/or blanking plate(s) configured to fit into multiple expansion slots. In particular, the cooling system includes one or more independent fluid-based cooling loops, each cooling loop including a modular fluid-to-air heat exchanger and a fluid flowing therethrough, one or more air movers configured to provide air to the fluid-to-air heat exchanger of each cooling loop, and an air plenum including a first end and a second end, wherein the first end is coupled to the one or more air movers and the second end is coupled to multiple expansion slots, wherein each fluid-to-air heat exchanger is configured to be removably coupled to one or more expansion slots such that each expansion slot coupled to the fluid-to-air heat exchanger is a used expansion slot and each expansion slot that is not coupled to the fluid-to-air heat exchanger is an unused expansion slot, further wherein a blanking plate is configured to be removably coupled to one or more unused expansion slots.

Other features and advantages of the present invention will become apparent after reviewing the detailed description of the embodiments set forth below.

### BRIEF DESCRIPTION OF THE DRAWINGS

FIG. 1 illustrates a front view of an exemplary radiator configuration.

FIG. 2 illustrates a front view of a radiator stack using the modular radiator configured in FIG. 1.

FIG. 3 illustrates a cut out side view of an exemplary air plenum configuration.

FIG. 4 illustrates an exemplary block diagram of the first cooling loop coupled to the air plenum in FIG. 3.

FIG. 5 illustrates an exemplary block diagram of an intermediate cooling loop coupled between the first cooling loop and the heat generating device of FIG. 4.

The present invention is described relative to the several views of the drawings. Where appropriate and only where identical elements are disclosed and shown in more than one drawing, the same reference numeral will be used to represent such identical elements.

### DETAILED DESCRIPTION OF THE PRESENT INVENTION

Embodiments of the present invention are directed to a scalable and modular cooling system that removes heat generated by one or more heat generating devices within a personal computer. The heat generating devices include, but are not limited to, one or more central processing units (CPU), a chipset used to manage the input/output of one or more CPUs, one or more graphics processing units (GPUs), and/or one or more physics processing units (PPUs), mounted on a motherboard, a daughter card, and/or a PC expansion card. The cooling system can also be used to cool power electronics, such as mosfets, switches, and other high-power electronics requiring cooling. In general, the cooling system described herein can be applied to any electronics sub-system that includes a heat generating device to be cooled. For simplicity, any sub-system installed within the personal computer that includes one or more heat generating devices to be cooled is referred to as a PC card.

The cooling system is configured to be scalable and modular such that as new PC cards including heat generating devices are added to the personal computer, additional cooling components are coupled to the cooling system. Additionally, already installed PC cards can be swapped for new or upgraded PC cards with corresponding alterations to the cooling system.

The cooling system is preferably configured within a personal computer chassis. Alternatively, the cooling system is configured as part of any electronics system that includes heat generating devices to be cooled. The cooling system includes one or more independent fluid-based cooling loops, an air plenum, one or more air movers, and one or more expansion slots. As described herein, reference to a single air mover is used. It is understood that the single air mover is representative of one or more air movers. Each air mover is preferably a fan. The air mover is coupled to a first end of the air plenum. The expansion slots are coupled to a second end of the air plenum. The air mover directs air through the air plenum toward the expansion slots. The air mover is coupled to the first end of the air plenum in a manner that substantially prevents air bypass between the air mover and the air plenum wall.

Each cooling loop includes a fluid-to-air heat exchanger, a pump, and at least one other heat exchanger. The components in the cooling loop are coupled via flexible fluid lines. In some embodiments, the fluid-to-air heat exchanger is a radiator. As described herein, reference to a radiator is used. It is understood that reference to a radiator is representative of any type of fluid-to-air heat exchanging system unless specific characteristics of the radiator are explicitly referenced. Each of the other heat exchangers in the cooling loop are coupled to either another heat exchanger, which is part of a different cooling loop or device, or to a heat generating device.

Each of the expansion slots functions as a receiving bay for one of the radiators. Each radiator is configured in a modular form so as to fit within any of the expansion slots coupled to the air plenum. In general, the air plenum includes N expansion slots and is scalable to receive up to N modular radiators within the N expansion slots. Each of the radiators is preferably configured to be stacked with other modular radiators. Such a configuration substantially prevents air bypass between stacked radiators. In general, each radiator is configured to be positioned adjacent to another modular radiator so as to prevent air bypass between the two. Adjacent radiators can be placed one on top of another or side-by-side.

Any expansion slots that are not used are fitted with removable blanking plates. Each blanking plate is configured so as to substantially prevent air bypass between an adjacently positioned radiator or another blanking plate. The second end of the air plenum is configured such that a radiator or a blanking plate positioned against the air plenum substantially prevents air bypass between the two. Each blanking plate includes one or more air thru-holes that allow air to pass through. The number of air thru-holes and the dimensions of each air thru-hole are configured so as to regulate an air flow-through rate through the corresponding expansion slot. In some embodiments, the configured air flow-through rate through an expansion slot fitted with a blanking plate is substantially equal to an air flow-through rate through an expansion slot fitted with a radiator. In this manner, a consistent air flow-through rate is provided through each expansion slot, regardless of whether or not the expansion slot is occupied with a radiator or a blanking plate. In other embodiments, the air flow-through rate through the blanking plate is configured according to a specific application, in which case the air flow-through rate through the blanking plate may or may not be the same as the air flow-through rate through other expansion slots. In some embodiments, the blanking plate is configured without air thru-holes.

In this configuration, the blanking plate prevents air from passing through the corresponding expansion slot.

Heat generated from a heat generating device is transferred to fluid flowing through the heat exchanger in the cooling loop. The heated fluid flows to the radiator, which is fitted within an expansion slot in the air plenum. The air mover blows air through each radiator fitted within the air plenum, thereby cooling the heated fluid flowing through each radiator. The cooled fluid then flows from the radiator back to the heat exchanger.

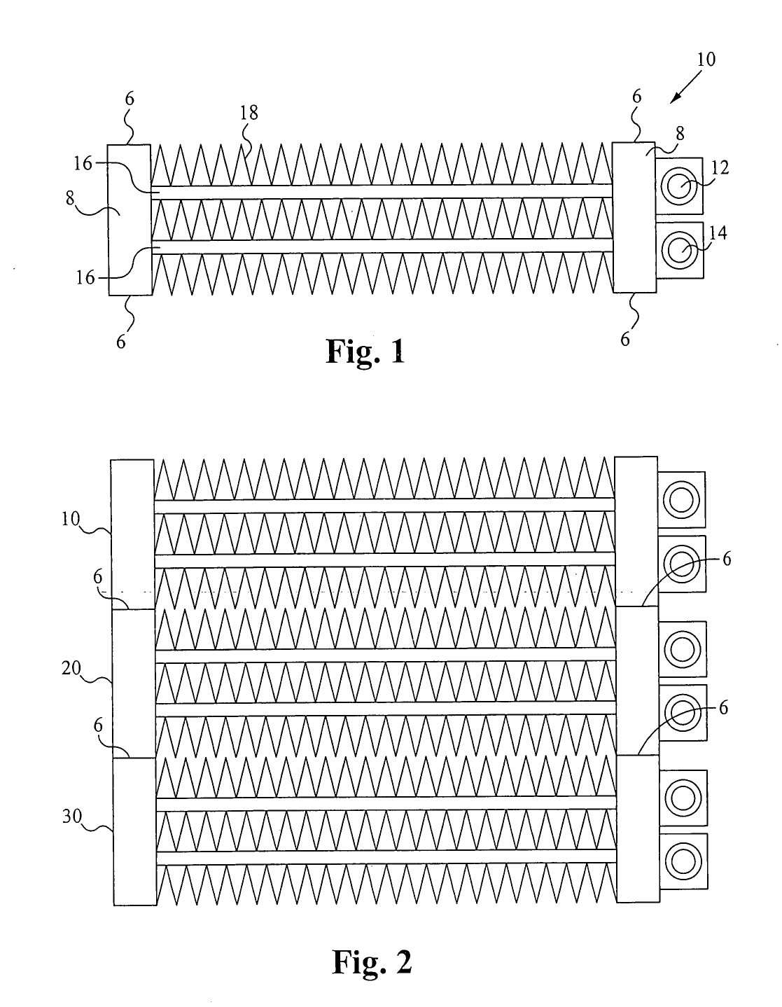

FIG. 1 illustrates a front view of an exemplary radiator used in the cooling loop and configured to be coupled with an expansion slot of the air plenum. The radiator 10 includes a plurality of fins 18 coupled to fluid channels 16. An inlet 12 and an outlet 14 are coupled to the fluid channels 16. The radiator 10 is configured to receive heated fluid via the inlet 12. The heated fluid flows through the channels 16. As the heated fluid flows through the channels 16, heat is transferred from the fluid to the fins 18. Cooled fluid flows out of the radiator 10 via the outlet 14. The fins 18 are cooled by blowing air over the outer surface of the fins.

The radiator 10 is configured in a modular shape so as to mate to an another adjacently positioned radiator. The radiator 10 includes a modular structure 8 that includes interface surfaces 6 configured to mate with complimentary interface surfaces on the adjacently positioned radiator. FIG. 2 illustrates a front view of a radiator stack using the modular radiator configured in FIG. 1. A radiator 20 and a radiator 30 are configured the same as the modular radiator 10. The radiator 10 is stacked on the radiator 20 via their respective mating surfaces 6. The radiator 20 is stacked on the radiator 30 via their respective mating surfaces 6. The interface formed at each mating surface 6 substantially prevents air from passing there between. The stacked radiators 10, 20, 30 are stacked one on top of the other and remain in position by gravity. Each radiator can also include additional retention means, such as interlocking clasps or channels, clips, or the like, to couple to another radiator. In some embodiments, an external retention means is applied to each end radiator, for example the radiator 10 and the radiator 30, in order to force and/or retain the radiator stack together. In some embodiments, the radiators are placed side-by-side.

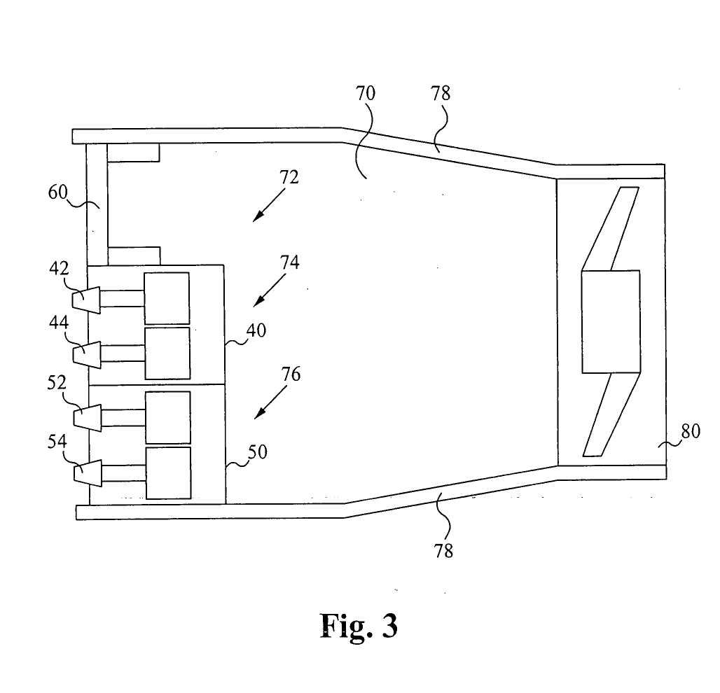

FIG. 3 illustrates a cut out side view of an exemplary air plenum configuration. An air plenum 70 is formed from walls 78. The air plenum 70 includes a plurality of expansion slots 72, 74, 76 and an air mover 80. The air plenum 70 is configured such that the air mover 80 is positioned at a first end of the air plenum 70, and the expansion slots 72, 74, 76 are positioned at a second end of the air plenum 70. The air plenum 70 is configured such that air blown by the air mover 80 is directed toward the second end of the air plenum 70. Although a single air mover 80 is shown in FIG. 3, more than one air mover can be used and positioned within the first end of the air plenum 70. Although three expansion slots 72, 74, 76 are shown in FIG. 3, more or less than three expansion slots can be used and positioned within the second end of the air plenum 70. Each expansion slot 72, 74, 76 is configured to receive either a radiator of the type described above in relation to FIGS. 1 and 2, or a blanking plate. The blanking plates and/or radiators are configured to stack together and fit within the second end of the air plenum 70 so as to substantially prevent air bypass. In other words, air directed from the air mover 80 is substantially prevented from passing between the blanking plates, the radiators, and/or the walls 78. Instead, the air passes through the blanking plates, when the blanking plates are configured with air thru-holes, and/or the radiators.

An exemplary configuration of the expansion slots is shown in FIG. 3. In this exemplary configuration, the expansion slot 72 is filled with a blanking plate 60, the expansion slot 74 is filled with a radiator 40, and the expansion slot 76 is filled with a radiator 50. The radiator 40 and the radiator 50 are the same as the radiator 10 in FIGS. 1 and 2. The radiator 40 and the radiator 50 are stacked together in a manner similar to that described in relation to radiators 10, 20, 30 in FIG. 2. As shown in FIG. 3, the radiators 40, 50 are shown from an end view, where the inlet 42, 52 and the outlet 44, 54 of each radiator 40, 50, respectively, is shown. The blanking plate 60 is configured with complimentary mating surfaces to the radiator 40 so as to substantially prevent air bypass between the blanking plate 60 and the radiator 40. In an alternative embodiment, the blanking plate is configured as a box or block with substantially the same dimensions as the radiator. Such a configuration substantially eliminates air-re-circulation, or eddies, within an expansion slot fitted with a blanking plate. In another alternative embodiment, the blanking plate is configured as a box, block, or other shape with dimensions larger than the radiator.

The blanking plate 60 preferably includes one or more air thru-holes (not shown) that allow air to pass through. The number of air thru-holes and the dimensions of each air thru-hole are configured so as to regulate the air flow-through rate through the expansion slot 72. In some embodiments, the configured air flow-through rate through the blanking plate 60, and therefore through the expansion slot 72, is substantially equal to an air flow-through rate through the radiator 40 in the expansion slot 74 and an air flow-through rate through the radiator 50 in the expansion slot 76. In this case, a consistent air flow-through rate is provided through each expansion slot 72, 74, 76. In other embodiments, the air flow-through rate through the blanking plate 60 is configured according to a specific application, in which case the air flow-through rate through the blanking plate 60 may or may not be the same as the air flow-through rate through the expansion slots 74, 76. In some embodiments, the blanking plate 60 is configured without air thru-holes. In this configuration, the blanking plate 60 prevents air from passing through the expansion slot 72.

The walls 78 of the air plenum 70 can be rigid or flexible, or a combination of both. For example, the portions of the walls 78 that interface with the air mover 80 and/or the expansion slots 72 and 76 are flexible to conform to the shape of any corresponding mating surfaces, while the remaining portion of the walls 78 is rigid to provide a support structure. In the preferred embodiment, the walls 78 are rigid and the portion of the walls 78 that interface with the expansion slot 72 and the expansion slot 74 are configured with complimentary mating surfaces to the radiator 40, and therefore also to the blanking plate 60, so as to substantially prevent air bypass between the wall 78 and the radiator 50 and between the wall 78 and the blanking plate 60.

The specific configuration of expansion slots with either blanking plates or radiators as shown in FIG. 3 is for exemplary purposes only. Each radiator and blanking plate is configured as a modular component that fits within any extension slot. As such, each expansion slot can be fitted with either a blanking plate or a radiator. For example, the expansion slot 74 and the expansion slot 76 can each be fitted with a blanking plate, and the expansion slot 72 can be fitted with a radiator. Where the air plenum is configured to stack radiators one on top of another, it is preferred that radiators are added to the expansion slots from the bottom up. For example, a first radiator is added to the bottom expansion slot 76, then as an additional radiator is added, the additional radiator is added at expansion slot 74. Any expansion slots that do not include radiators are preferably fitted with blanking slots from the top expansion slot downward, as shown in FIG. 3. Alternatively, there is no preferred order by which the radiators are added to the expansion slots. In this case, the interface surfaces of each blanking plate that mate to a radiator (or another blanking plate or a wall of the air plenum) are configured with substantially the same dimensions as the corresponding interface surfaces of the radiator. In this manner, blanking plates are stacked within or under one or more radiators in a stable configuration.

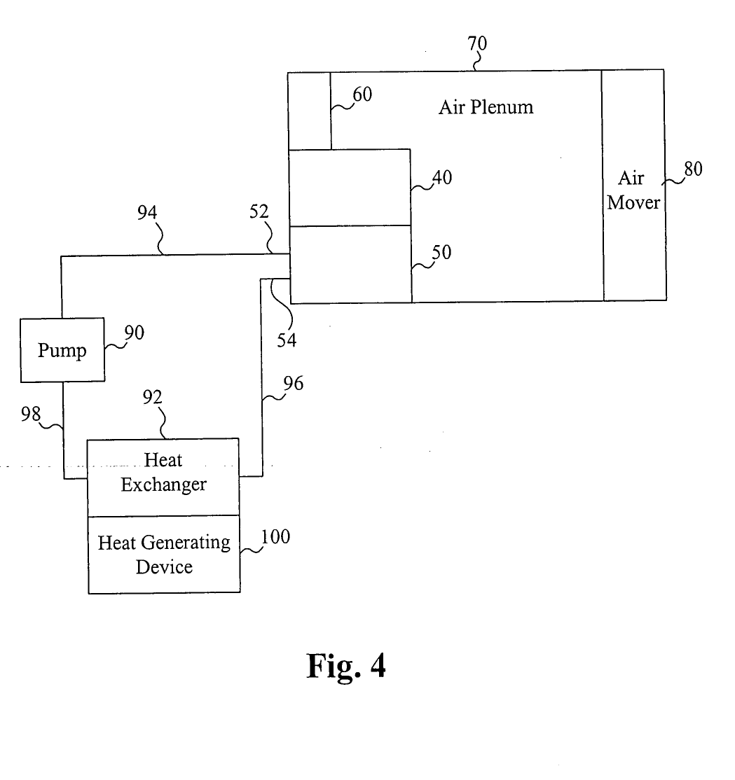

Each radiator is coupled to an independent cooling loop. In particular, the radiator 50 is coupled to a first cooling loop, and the radiator 40 is coupled to a second cooling loop. The first cooling loop is independent of the second cooling loop. FIG. 4 illustrates an exemplary block diagram of the first cooling loop coupled to the air plenum 70. For simplicity, only the first cooling loop coupled to the radiator 50 is shown in FIG. 4 and described further below. It is understood that the radiator 40 is similarly coupled to the second cooling loop, although the second cooling loop is not shown in FIG. 4, nor described in detail below. The first cooling loop includes the radiator 50, a pump 90, and a heat exchanger 92, each coupled via fluid lines 94, 96, 98. In this configuration, the first cooling loop is coupled to the radiator inlet 52 via fluid line 94 and to the radiator outlet 54 via fluid line 96. It is understood that the fluid lines, and therefore the fluid flow through the first cooling loop, can be reversed by coupling the fluid line 96 to the radiator inlet 52 and the fluid line 94 to the radiator outlet 54. It is also understood that the relative position of each component in the first cooling loop is for exemplary purposes only. For example, the pump 90 can be positioned on the inlet side of the heat exchanger 92, instead of the outlet side as shown in FIG. 4.

The heat exchanger 92 is coupled to a heat generating device 100. Any conventional coupling means can be used to couple the heat exchanger 92 to the heat generating device 100. Preferably, a removable coupling means is used to enable the heat exchanger to be removed and reused. Alternatively, a non-removable coupling means is used. Heat generated by the heat generating device is transferred to fluid flowing through the heat exchanger 92. The heated fluid is output from the heat exchanger 92 and input to the radiator 50. Although the first cooling loop includes a single heat exchanger 92, the first cooling loop can include more than one heat exchanger coupled in series or parallel to the heat exchanger 92. In this manner, the first cooling loop can be used to cool multiple heat generating devices, where the multiple heat generating devices are all coupled to a single PC card or are distributed on multiple PC cards. The second cooling loop that includes the radiator 40 can be configured the same as or differently than the first cooling loop. Such design flexibility enables application-specific configurations for each cooling loop. Combined with various air thru-hole configurations of the blanking plates, application-specific design flexibility is further enhanced.

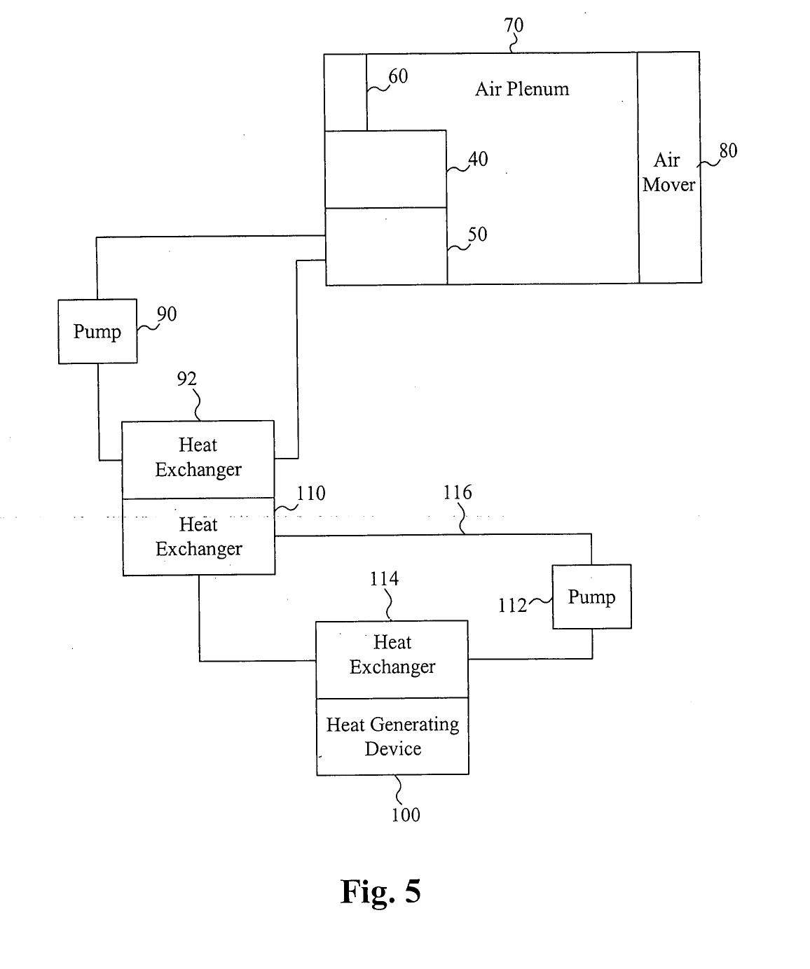

In an alternative embodiment, an intermediary cooling loop is coupled between the first cooling loop and the heat generating device 100. FIG. 5 illustrates an exemplary block diagram of an intermediate cooling loop coupled between the first cooling loop and the heat generating device 100 of FIG. 4. The intermediate cooling loop is independent of the first cooling loop. The intermediate cooling loop includes a heat exchanger 110, a pump 112, and another heat exchanger 114, all coupled via fluid lines 116. The heat exchanger 110 is coupled to the heat exchanger 92. The heat exchanger 114 is coupled to the heat generating device 110 in a manner similar to the heat exchanger 92 coupled to the heat generating device in FIG. 4. The heat exchanger 92 is similarly coupled to the heat exchanger 110, thereby forming a thermal interface between the two. Although the intermediate cooling loop includes a single heat exchanger 114 for coupling to a heat generating device, the intermediate cooling loop can include more than one such heat exchanger coupled in series or parallel to the heat exchanger 114.

Heat generated by the heat generating device 100 is transferred to fluid flowing through the heat exchanger 114. The heated fluid is output from the heat exchanger 114 and input to the heat exchanger 110. Heat is transferred from the heat exchanger 110 to the heat exchanger 92 via the thermal interface formed between the two. Heat transferred from the heat exchanger 110 to the heat exchanger 92 is then transferred to fluid flowing through the heat exchanger 92. The heated fluid is output from the heat exchanger 92 and input to the radiator 50. An exemplary method of transferring heat from a heat generating device to a fluid-to-air heat exchanger via two or more independent fluid cooling loops is described in detail in the co-owned U.S. patent application Ser. No. 11/707,350, filed Feb. 16, 2007, and entitled “Liquid Cooling Loops for Server Applications”, which is hereby incorporated in its entirety by reference.

In yet another alternative embodiment, the heat exchanger 92 of the first cooling is coupled to a thermal bus, where the thermal bus is capable of interfacing with a plurality of heat exchangers from a plurality of different cooling loops. Such a configuration is described in the co-owned U.S. patent application Ser. No. (Cool 05201), filed on Apr. 6, 2007, and entitled “Methodology of Cooling Multiple Heat Sources in a Personal Computer Through the Use of Multiple Fluid-based Heat Exchanging Loops Coupled via Modular Bus-type Heat Exchangers”, which is hereby incorporated in its entirety by reference.

In the embodiments described above, each radiator is configured to fit within a single expansion slot. In alternative embodiments, a single radiator can be configured to fit within multiple expansion slots. For example, a single radiator is configured to be the size of the radiators 40 and 50 (FIG. 3) stacked together, in which case the single radiator fits within two adjacent expansion slots. In general, a size of a radiator can be configured in multiples of the modular radiator 10 (FIG. 1) described above. Similarly, a size of a single blanking plate can be configured as a multiple of the blanking plate 60 (FIG. 3), in which case the single blanking plate fits within a corresponding multiple of adjacent expansion slots. Combinations of any multiple-configured modular radiator(s) and any multiple-configured modular blanking plate(s) can be used to fill all expansion slots.

It is apparent to one skilled in the art that the present cooling system is not limited to the components shown in FIG. 1-5 and alternatively includes other components and devices. For example, although not shown in FIG. 4, the first cooling loop can also include a fluid reservoir. The fluid reservoir accounts for fluid loss over time due to permeation.

Additionally, although each of the embodiments described above in regards to FIGS. 1-5 are directed to fluid-based and pumped cooling loops, alternative cooling systems, such as heat pipes and conduction means, can be used. It is also contemplated that a single cooling system can be configured with one or more pumped cooling loops and one or more heat pipe-based cooling loops.

In some embodiments, the cooling system is configured to cool each heat generating device included within a PC chassis. In other embodiments, the cooling system is configured to cool only select heat generating devices, or only a single heat generating device, while other heat generating devices are left to be cooled by other or complimentary means.

The present invention has been described in terms of specific embodiments incorporating details to facilitate the understanding of the principles of construction and operation of the invention. Such reference herein to specific embodiments and details thereof is not intended to limit the scope of the claims appended hereto. It will be apparent to those skilled in the art that modifications may be made in the embodiment chosen for illustration without departing from the spirit and scope of the invention.

What is claimed is:

1. A cooling system for cooling one or more heat generating devices within a personal computer, the cooling system comprising:
a. one or more independent fluid-based cooling loops, each cooling loop including a modular fluid-to-air heat exchanger and a fluid flowing therethrough;
b. one or more air movers configured to provide air to the fluid-to-air heat exchanger of each cooling loop; and
c. an air plenum including a first end and a second end, wherein the first end is coupled to the one or more air movers and the second end is coupled to multiple receiving bays, wherein each receiving bay is configured to accommodate one removable fluid-to-air heat exchanger from a corresponding cooling loop, further wherein each receiving bay is configured to accommodate one removable blanking plate such that each receiving bay is configured with one fluid-to-air heat exchanger or one blanking plate.

2. The cooling system of claim 1 wherein each modular fluid-to-air heat exchanger is configured to be stacked with another modular fluid-to-air heat exchanger present within an adjacent receiving bay.

3. The cooling system of claim 1 wherein each modular fluid-to-air heat exchanger is configured to be interlocked with another modular fluid-to-air heat exchanger present within an adjacent receiving bay.

4. The cooling system of claim 1 wherein each modular fluid-to-air heat exchanger, each blanking plate, and the second end of the air plenum are configured to substantially prevent air bypass through the second end of the air plenum.

5. The cooling system of claim 1 wherein the one or more air movers and the first end of the air plenum are configured to substantially prevent air bypass through the first end of the air plenum.

6. The cooling system of claim 1 wherein each blanking plate is configured to prevent air from flowing through the receiving bay to which the blanking plate is coupled.

7. The cooling system of claim 1 wherein each blanking plate includes one or more air thru-holes, wherein a number of air thru-holes and a dimension of each air thru-hole is configured to provide a specific air flow-through rate through the receiving bay to which the blanking plate is coupled.

8. The cooling system of claim 7 wherein the air flow-through rate of each blanking plate substantially equals an air-flow-through rate through the receiving bay to which one modular fluid-to-air heat exchanger is coupled, thereby generating a substantially equal air flow-through rate through each receiving bay.

9. The cooling system of claim 1 wherein each cooling loop further comprises one or more heat exchangers and a pump.

10. The cooling system of claim 1 wherein each air mover comprises a fan.

11. The cooling system of claim 1 wherein each fluid-to-air heat exchanger comprises a radiator.

12. A cooling system for cooling one or more heat generating devices within a personal computer, the cooling system comprising:
a. one or more independent fluid-based cooling loops, each cooling loop including a modular fluid-to-air heat exchanger and a fluid flowing therethrough;
b. one or more air movers configured to provide air to the fluid-to-air heat exchanger of each cooling loop; and
c. an air plenum including a first end and a second end, wherein the first end is coupled to the one or more air movers and the second end is coupled to multiple expansion slots, wherein each expansion slot is configured to receive one removable fluid-to-air heat exchanger from a corresponding cooling loop such that each expansion slot that receives one fluid-to-air heat exchanger is a used expansion slot and each expansion slot that does not receive one fluid-to-air heat exchanger is an unused expansion slot, further wherein each unused expansion slot is configured to receive one removable blanking plate.

13. The cooling system of claim 12 wherein each modular fluid-to-air heat exchanger is configured to be stacked with another modular fluid-to-air heat exchanger present within an adjacent expansion slot.

14. The cooling system of claim 12 wherein each modular fluid-to-air heat exchanger is configured to be interlocked with another modular fluid-to-air heat exchanger present within an adjacent expansion slot.

15. The cooling system of claim 12 wherein each modular fluid-to-air heat exchanger, each blanking plate, and the second end of the air plenum are configured to substantially prevent air bypass through the second end of the air plenum.

16. The cooling system of claim 12 wherein the one or more air movers and the first end of the air plenum are configured to substantially prevent air bypass through the first end of the air plenum.

17. The cooling system of claim 12 wherein each blanking plate is configured to prevent air from flowing through the expansion slot to which the blanking plate is coupled.

18. The cooling system of claim 12 wherein each blanking plate includes one or more air thru-holes, wherein a number of air thru-holes and a dimension of each air thru-hole is configured to provide a specific air flow-through rate through the expansion slot to which the blanking plate is coupled.

19. The cooling system of claim 18 wherein the air flow-through rate of each blanking plate substantially equals an air-flow-through rate through the expansion slot to which one modular fluid-to-air heat exchanger is coupled, thereby generating a substantially equal air flow-through rate through each expansion slot.

20. The cooling system of claim 12 wherein each cooling loop further comprises one or more heat exchangers and a pump.

21. The cooling system of claim 12 wherein each air mover comprises a fan.

22. The cooling system of claim 12 wherein each fluid-to-air heat exchanger comprises a radiator.

23. A cooling system for cooling one or more heat generating devices within a personal computer, the cooling system comprising:
a. one or more independent fluid-based cooling loops, each cooling loop including a modular fluid-to-air heat exchanger and a fluid flowing therethrough;
b. one or more air movers configured to provide air to the fluid-to-air heat exchanger of each cooling loop; and
c. an air plenum including a first end and a second end, wherein the first end is coupled to the one or more air movers and the second end is coupled to multiple expansion slots, wherein each fluid-to-air heat exchanger is configured to be removably coupled to one or more expansion slots such that each expansion slot coupled to the fluid-to-air heat exchanger is a used expansion slot and each expansion slot that is not coupled to the fluid-to-air heat exchanger is an unused expansion slot, further wherein a blanking plate is configured to be removably coupled to one or more unused expansion slots.

24. The cooling system of claim 23 wherein each modular fluid-to-air heat exchanger is configured to be stacked with another modular fluid-to-air heat exchanger present within an adjacent expansion slot.

25. The cooling system of claim 23 wherein each modular fluid-to-air heat exchanger is configured to be interlocked with another modular fluid-to-air heat exchanger present within an adjacent expansion slot.

26. The cooling system of claim 23 wherein each modular fluid-to-air heat exchanger, each blanking plate, and the second end of the air plenum are configured to substantially prevent air bypass through the second end of the air plenum.

27. The cooling system of claim 23 wherein the one or more air movers and the first end of the air plenum are configured to substantially prevent air bypass through the first end of the air plenum.

28. The cooling system of claim 23 wherein each blanking plate is configured to prevent air from flowing through the one or more expansion slots to which the blanking plate is coupled.

29. The cooling system of claim 23 wherein each blanking plate includes one or more air thru-holes, wherein a number of air thru-holes and a dimension of each air thru-hole is configured to provide a specific air flow-through rate through each of the one or more expansion slots to which the blanking plate is coupled.

30. The cooling system of claim 29 wherein the air flow-through rate through each expansion slot substantially equal.

31. The cooling system of claim 23 wherein each cooling loop further comprises one or more heat exchangers and a pump.

32. The cooling system of claim 23 wherein each air mover comprises a fan.

33. The cooling system of claim 23 wherein each fluid-to-air heat exchanger comprises a radiator.
